(19) United States
(12) Patent Application Publication
(10) Pub. No.: US 2012/0024347 A1
(43) Pub. Date: Feb. 2, 2012

(54) SOLAR PACKAGE STRUCTURE AND METHOD FOR FABRICATING THE SAME

(76) Inventors: Tzy-Ying Lin, Hsinchu City (TW); Shang-Jen Yu, Hsinchu City (TW); Jau-Jan Deng, Taipei City (TW)

(21) Appl. No.: 12/844,618

(22) Filed: Jul. 27, 2010

(51) Int. Cl. H01L 31/048; H01L 31/18; H01L 31/042

(52) U.S. Cl. 136/251; 136/244; 438/65; 438/66; 257/E31.113; 257/E31.127

(57) ABSTRACT

The invention provides a solar package structure and a method for fabricating the same. A solar package structure includes a carrier wafer. A conductive pattern layer is disposed on the carrier wafer. A solar cell chip array is disposed on the conductive pattern layer, wherein the solar cell chip array electrically connects to the conductive pattern layer. A first spacer dam is disposed on the carrier wafer, surrounding the solar cell chip array. A first optical element array is disposed over the carrier wafer to concentrate sunbeams onto the solar cell chip array, wherein the first optical element array is spaced apart from the carrier wafer by the first spacer dam.

### BACKGROUND OF THE INVENTION

1. Field of the Invention

The present invention relates to a solar package structure and a method for fabricating the same, and in particular, to a solar package structure using a wafer level packaging process and a method for fabricating the same.

2. Description of the Related Art

A solar cell is a device that converts the energy of sunlight directly into electricity by photovoltaic effect. The size and weight of the conventional solar cell is limited to a large module size of 10 cm×10 cm×10-20 cm and a heavy module weight of more than 4 kg, respectively. The lens of conventional solar cell concentrates sunbeams on to only one solar cell chip. Thus, heat from the conventional solar cell dissipates slowly when temperature thereof increases. Accordingly, heat sinks are used to hinder heat dissipation. However, with the added heat sinks, the weight of the module of the conventional solar cell is increased. Meanwhile, the lens of a large-sized conventional solar cell has a long focus length. Thus, a solar cell chip thereof has a small accept angle (half of the angular aperture of an optical system) of less than 0.5 degree. Also, because a highly accurate sun tracker is required in the conventional solar cell to track the sun, fabrication costs are high.

Thus, a novel solar package structure and a method for fabricating the same are desired.

### BRIEF SUMMARY OF INVENTION

A solar package structure and a method for fabricating the same are provided. An exemplary embodiment of a solar package structure comprises a carrier wafer. A solar package structure includes a carrier wafer. A conductive pattern layer is disposed on the carrier wafer. A solar cell chip array is disposed on the conductive pattern layer, wherein the solar cell chip array electrically connects to the conductive pattern layer. A first spacer dam is disposed on the carrier wafer, surrounding the solar cell chip array. A first optical element array is disposed over the carrier wafer to concentrate sunbeams onto the solar cell chip array, wherein the first optical element array is spaced apart from the carrier wafer by the first spacer dam.

An exemplary embodiment of method for fabricating a solar package structure, comprising providing a carrier wafer. A conductive pattern layer is formed on the carrier wafer. A solar cell chip array having a plurality of solar cell chips is disposed on the conductive pattern layer, wherein each of the solar cell chips electrically connects to the conductive pattern layer. A first spacer dam is disposed on the carrier wafer, surrounding the solar cell chip array. A first optical element array is disposed over the carrier wafer to concentrate sunbeams onto the solar cell chip array, wherein the first optical element array is spaced apart from the carrier wafer by the first spacer dam.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a top view of one exemplary embodiment of a solar package structure of the invention.

FIG. 2 is a cross section view taken along line A-A′ of FIG. 1.

FIGS. 3 to 6 are cross section views showing one exemplary embodiment of a method for fabricating a solar package structure of the invention.

FIG. 7 is a cross section view showing another exemplary embodiment of a method for fabricating a solar package structure of the invention.

FIG. 8 is a cross section view showing another exemplary embodiment of a solar package structure of the invention.

FIG. 9 is a cross section view showing yet another exemplary embodiment of a solar cell chip package

Table. 1 is a comparison table of one exemplary embodiment of a solar package structure of the invention versus a conventional solar package structure.

### DETAILED DESCRIPTION OF INVENTION

The following description is of a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

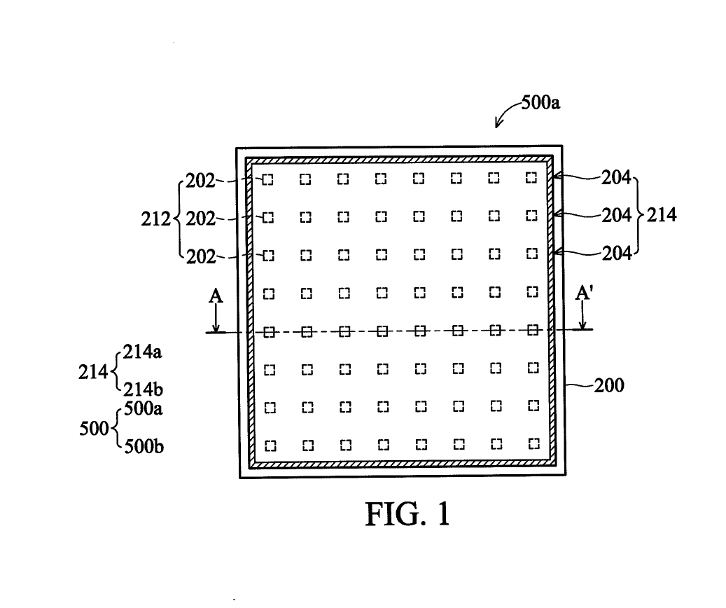

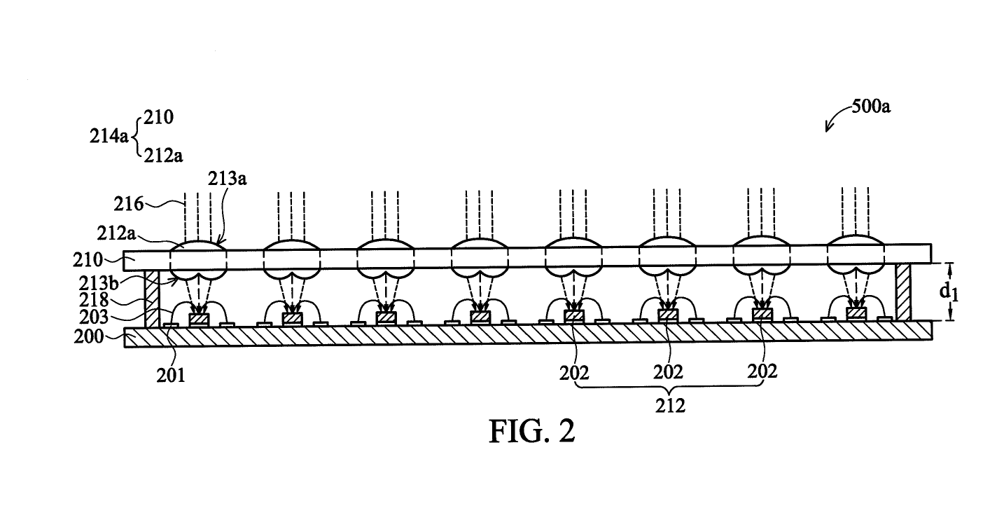

FIG. 1 is a top view of one exemplary embodiment of a solar package structure 500a of the invention. FIG. 2 is a cross section view taken along line A-A′ of FIG. 1. The solar cell chip package 500a, such as concentrating photovoltaic (CPV) solar cell chip package 500a, is fabricated by a wafer level packaging process. As shown in FIGS. 1 and 2, the solar cell chip package 500a comprises a carrier wafer 200. A conductive pattern layer 201 is disposed on the carrier wafer 200. A solar cell array 212 comprising a plurality of solar cell chips 202 is disposed on the conductive pattern layer 201. A first spacer dam 218 is disposed on the carrier wafer 200, surrounding the solar cell array 212. A first optical element array 214a is disposed over the carrier wafer 200 for allowing sunbeams 216 to be concentrated to the solar cell chips 202, wherein the first optical element array 214a is spaced apart from the carrier wafer 200 by the first spacer dam 214 connecting therebetween. In one embodiment, the carrier wafer 200 serving as a carrier and/or a heat dissipation element for the solar cell array 212 may comprise dielectric materials such as silicon, ceramic or the like, or metal materials such as Al or the like. In one embodiment, the solar cell chips 202 work with a doped semiconductor to produce two different regions separated by a p-n junction. Each of the solar cell chips 202 may have at least two electrodes thereon, wherein the electrodes comprise an anode electrode and a cathode electrode which are connected to two different regions of the p-n junction. In one embodiment, the conductive pattern layer 201 may have a plurality of isolated conductive patterns to electrically connect to the different electrodes of the solar cell chips 202 to transmit electro signals transformed by the solar cell chips 202 the solar cell chips 202. The conductive pattern layer 201 may comprise conductive materials such as Al, Cu, Ni, Au, Ag, Sn, Pd, W, Cr or the like. If the carrier wafer 200 is a printed circuit board, the solar cell chips 202 may directly connect to the carrier wafer 200 without the conductive pattern layer 201. In one embodiment, the first optical element array 214a may be a plurality of first optical elements 204a arranged as an array. The first optical element array 214a may be composed of a first transparent plate 210 and a first lens array having a plurality of first lenses 212 formed thereon. The first transparent plate 210 and the first lenses 212 may be comprised of transparent materials such as glass or acryl. Each of the first lenses 212 is directly over each of the solar cell chips 202. Alternatively, the first optical element array 214a may further comprise reflectors (not shown) to further concentrate the sunbeams 216 onto the solar cell chips 202. The first spacer dam 218 may serve as a spacer to separate the first optical element array 214a and the carrier wafer 200 by a height d₁, thereby facilitating focus of the sunbeams 216 onto the surfaces of the solar cell chips 202. In one embodiment, the first spacer dam 218 may comprise inorganic or organic insulating materials such as oxide, nitride, polyimide or the like, or combinations thereof.

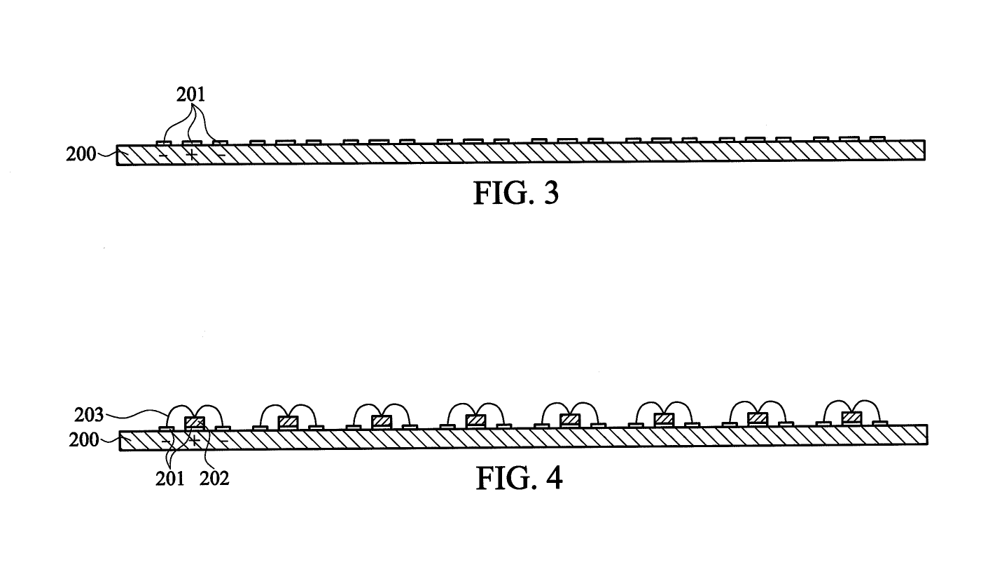

FIGS. 3 to 6 are cross section views showing one exemplary embodiment of a method for fabricating a solar package structure 500a of the invention. As shown in FIG. 3, a carrier wafer 200 is provided. Next, a conductive pattern layer 201 having a plurality of isolated conductive patterns is formed on the carrier wafer by a deposition and a patterning processes.

Referring to FIG. 4, a solar cell chip array 212 having a plurality of solar cell chips 202 is disposed on the conductive pattern layer 201. For one embodiment as shown in FIG. 4, each of the solar cell chips 202 is respectively disposed on one of the conductive patterns, wherein an anode of the solar cell chip 202 electrically connects to the conductive pattern, and a cathode of the solar cell chip 202 electrically connects to the other conductive patterns neighboring the conductive pattern by conductive wires 203.

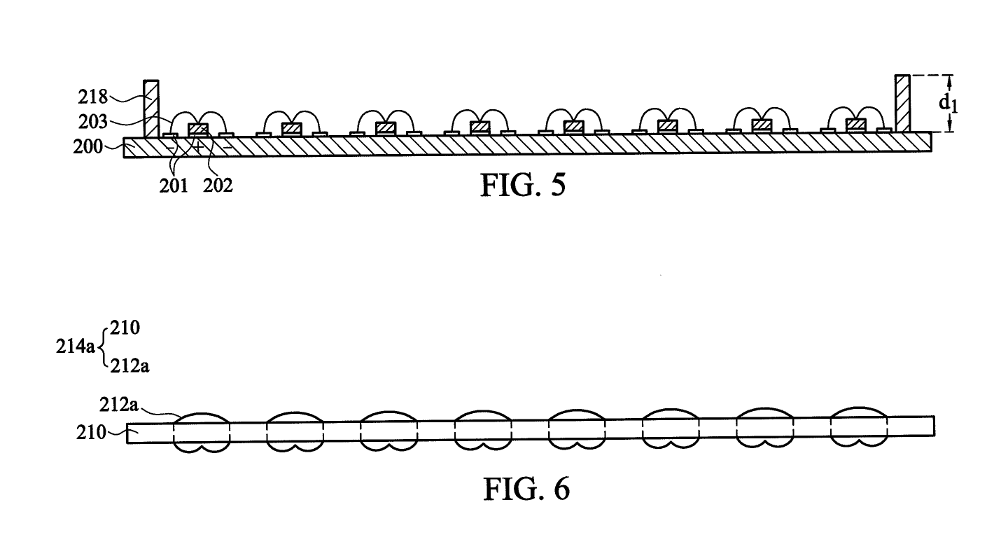

Next, referring to in FIG. 5, a first spacer dam 218 is disposed on the carrier wafer 200, surrounding each of the solar cell chips 202 by an assembly process, for example, the first spacer dam 218 and the carrier wafer 200 are assembled using a glue. As shown in FIG. 5, the first spacer dam 218 may have a height d₁ larger than that of the solar cell chip 202 to assure the following assembling first optical element array 214a without contacting to the solar cell chips 202.

Next, referring to FIG. 6, the wafer level first optical element array 214a is fabricated and assembled to the carrier wafer 200. As shown in FIG. 6, the first lens 212a may be formed by a molding process, wherein a focus of the first lens 212a defines the height d₁ of the first spacer dam 218.

Next, referring to FIG. 2, the fabricated first optical element array 214a is assembled to the carrier wafer 200 by disposal thereon, to concentrate sunbeams 216 onto the solar cell chip array 212. The first optical element array 214a is spaced apart from the carrier wafer 200 by the first spacer dam 218 connected therebetween. After the aforementioned fabricating process, one exemplary embodiment of a solar package structure 500a is completely formed.

As shown in FIG. 2, in one embodiment, the first lens 212a of the first optical element 204a is a biconvex lens having a first convex surface 213a facing the direction of sunbeams 216 and a second convex surface 213b facing the solar cell chip 202. In one embodiment as shown in FIG. 2, the second convex surface 213b is a wave-shaped surface.

Table. 1 is a comparison table of one exemplary embodiment of a solar package structure 500a of the invention versus a conventional solar package structure.

| | | Focus | | | Chip |
|---|---|---|---|---|---|
| 1. Module Characters | Cell Area | length | Weight | Chip Size | Number |
| Conventional solar cell | 12 cm × 12 cm | >10 cm | >2000 g | 5.5 mm × 5.5 mm | ×1 ea |
| Solar package structure | 12 cm × 12 cm | <1.0 cm | <100 g | 400 μm × 400 μm | ×200 ea |
| 500a | | | | | |

| | Power | Acceptance | Tracker | Temp. | |
|---|---|---|---|---|---|
| 2. Performance | Generate | Angle | Used | Generation | Heat Sink |
| Conventional solar cell | ~3 W | 0.5-1.5 | complicated | >50° C. | Need |
| | | degree | | | |
| Solar package structure | ~3 W | >2 degree | simple | <10° C. | No |
| 500a | | | | | |

Table. 1 is a comparison table of one exemplary embodiment of a solar package structure 500a of the invention versus 45a conventional solar package structure. From Table 1, it is shown that the solar package structure 500a has the following advantages. First, the size of the solar package structure 500a fabricated by using a wafer level packaging process, may be a small size of about 400 μm×400 μm. When considering the standard module area of 12 cm×12 cm, for only one chip of the conventional solar cell, the solar package structure 500a may allow about 200 chips versus 1 chip for the conventional solar cell. Also, the module weight of the solar package structure 500a is less than 100 g, which is much lighter than the conventional solar cell. Thus, because of the smaller size of the solar package structure 500a, focus length thereof may be reduced to less than 1 cm. Accordingly, an accepted angle of the solar package structure 500a may be larger than 2 degrees. Therefore, a sun tracker used in the solar package structure 500a having a larger accepted angle may be simpler or with a lower accuracy for tracking sun than the conventional solar cell. Additionally, due to the increased chip number of the solar package structure 500a, the sunbeams may be concentrated on various positions of the carrier wafer 200 where the solar cell chips are disposed, so that heat from the sunbeams may dissipate more easily. As shown in Table 1, the solar package structure 500a may have a low temperature of less than 10° C. due to sunbeams, without the use of additional heat sink devices. Therefore, the solar package structure 500a may have improved efficiency and reliability. Accordingly, fabrication of the solar package structure 500a may be reduced.

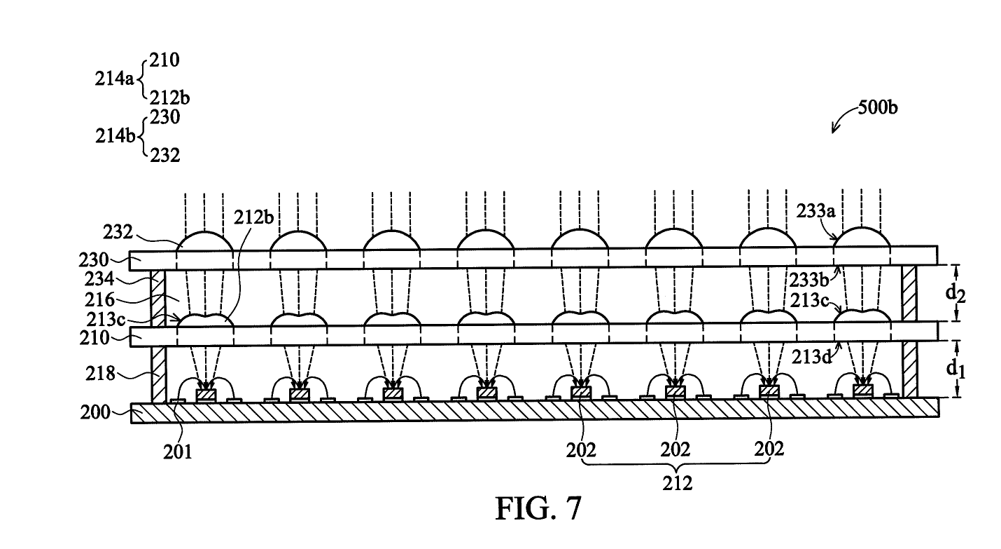

Alternatively, the solar package structure may comprise two or more than two concentrating optical element arrays, which are laminated vertically, for further light concentration requirements. FIG. 7 is a cross section view showing another exemplary embodiment of a method for fabricating a solar cell chip package structure 500b of the invention. Elements of the embodiments hereinafter, that are the same or similar as those previously described with reference to FIGS. 2 to 6, are not repeated for brevity. After disposing the first optical element array 214a over the carrier wafer 200, a second spacer dam 234 is then disposed on the first optical element array 214a. As shown in FIG. 7, the second spacer dam 234 may be disposed directly over the first spacer dam 218, and the materials of the second spacer dam 234 may be the same as that of the first spacer dam 218. The second spacer dam 234 may have a height d₂ larger than that of first lenses 212b to assure following assembling second optical element array 214b without contacting to the first lenses 212b. Next, another wafer level second optical element array 214b is fabricated and provided for assembly to the carrier wafer 200, and disposed over the first optical element array 214a. Similar to the first optical element array 214a, the second optical element array 214b may comprise a second transparent plate 230 with a second lens array comprising a plurality of second lenses 232 formed thereon, wherein each of the second lenses 232 is directly over one the first lenses 212b. The first and second optical element arrays 214a and 214b are spaced apart from each other by the second spacer dam 234 connecting therebetween, and a focus of the second lenses 232 defines the height d₂ of the second spacer dam 234. After the aforementioned fabricating process, another exemplary embodiment of a solar package structure 500b is completely formed.

As shown in FIG. 7, the first lens 212b of the first optical element array 214a is a plano-convex lens having a convex surface 213c facing the direction of sunbeams 216 and a plane surface 213d facing the solar cell chip 202. In one embodiment as shown in FIG. 7, the convex surface 213c is a wave-shaped surface. The second optical element array 214b is a plano-convex lens having a convex surface 233a facing the direction of sunbeams 216 and a plane surface 233b facing the solar cell chip 202. The solar package structure 500b may have advantages, such as improved light concentration, in addition to the previously mentioned advantages of the solar package structure 500a.

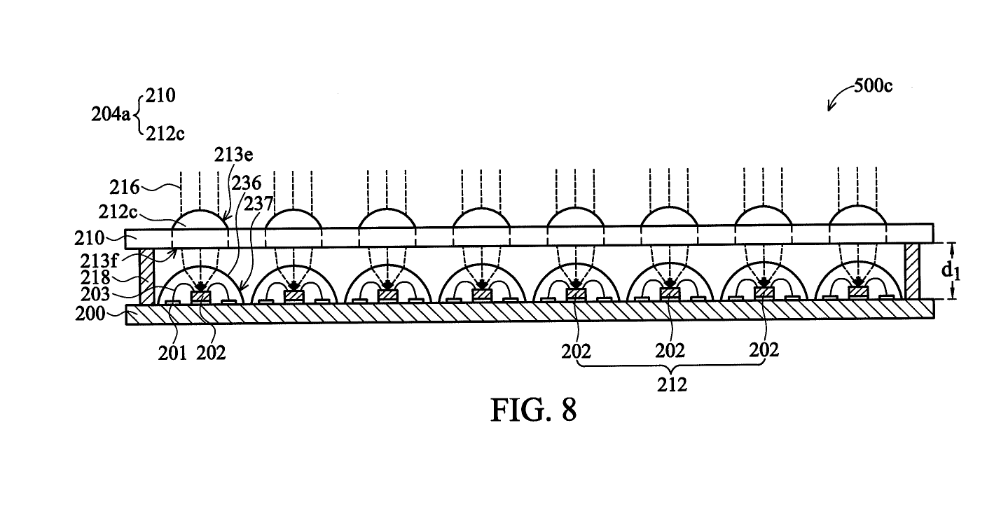

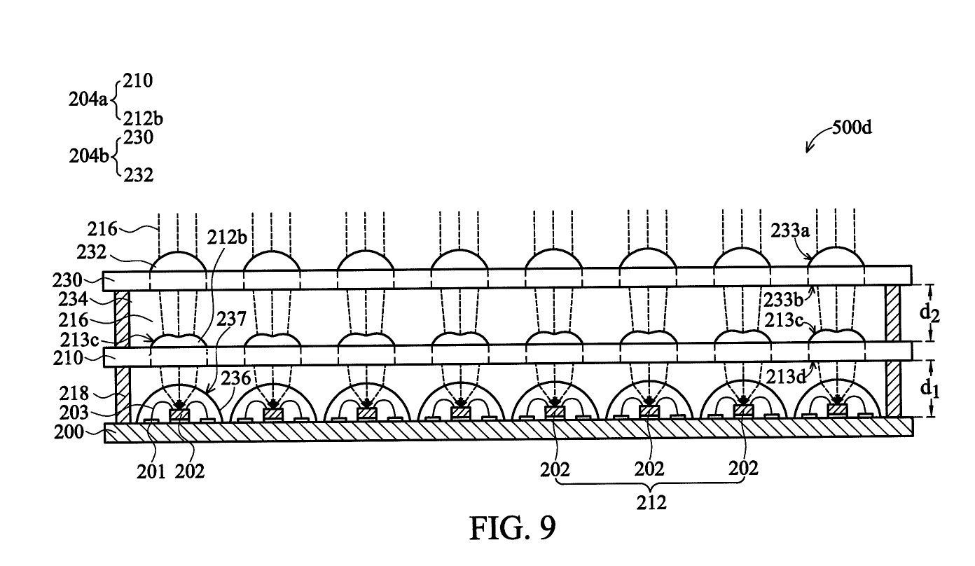

Alternatively, several embodiments may be employed to further concentrate sunbeams onto the solar cell chips as shown in FIGS. 8 to 9. FIG. 8 is a cross section view showing another exemplary embodiment of a solar cell chip package 500c. The solar cell chip package 500c with the first optical element array 214a may have a plurality of transparent molds 236 disposed directly under first lenses 212c, respectively encapsulating the solar cell chips 202, the conductive pattern layer 201 and the conductive wires 203. Each of the transparent molds 236 has a convex surface 237 facing the first optical element 204a, and a focus of the transparent molds 236 is designed on the surface of the solar cell chip 202 for further concentration of sunbeams. In one embodiment, the transparent molds 236 may be formed by a molding process before forming the first dam 210. In one embodiment, the transparent molds 236 may comprise transparent insulating materials such as polyimide or epoxy. The first lenses 212c of the first optical element array 214a is a plano-convex lens having a convex surface 213e facing the direction of sunbeams 216 and a plane surface 213f facing the solar cell chip 202.

FIG. 9 is a cross section view showing yet another exemplary embodiment of a solar cell chip package 500d. The solar cell chip package 500d, with vertically laminated first and second optical element arrays 214a and 214b, may also have a plurality transparent molds 236 disposed directly under a first lenses 212b, respectively encapsulating the solar cell chip 202, the conductive pattern layer 201 and the conductive wires 203. Each of the transparent molds 236 has a convex surface 237 facing the first optical element 204a, and a focus of the transparent molds 236 is designed on the surface of the solar cell chip 202 for further light concentration. In one embodiment, the transparent molds 236 may be formed by a molding process before forming the first dam 210. In one embodiment, the transparent molds 236 may comprise transparent insulating materials such as polyimide or epoxy. The characteristics of the first lenses 212b of the first optical element array 214a and the second lenses 232 of the second optical element array 214b are similar to those of the solar cell chip package 500b.

Compared with the conventional solar cell, the solar package structure fabricated using a wafer level packaging process is smaller. When considering the standard module area, for only one chip of the conventional solar cell, the solar package structure of the invention may allow a greater number of chips to be disposed thereon. Also, the module weight of the solar package structure of the invention is much lighter than the conventional solar cell. Thus, because of the smaller size of the solar package structure of the invention, focus length thereof may be reduced. Accordingly, an accepted angle of the solar package structure 500a may be larger than 2 degrees. Therefore, a sun tracker used in the solar package structure of the invention may have a large accepted angle, and a simpler assembly process. Additionally, because the number of chips of the solar package structure 500 is increased, sunbeams may be concentrated on various positions of the carrier wafer where the solar cell chips are disposed, so that heat from the sunbeams may dissipate more easily. The solar package structure of the invention may have a low enough operation temperature, such that additional heat sink devices are not required. Therefore, the solar package structure of the invention may be more efficient and reliable than the conventional solar cell. Therefore, the solar package structure of the invention has reduced fabrication costs, and can be applied to small-size concentrating photovoltaic (CPV) systems.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar package structure, comprising:
a carrier wafer;
a conductive pattern layer disposed on the carrier wafer;
a solar cell chip array disposed on the conductive pattern layer, wherein the solar cell chip array electrically connects to the conductive pattern layer;
a first spacer dam disposed on the carrier wafer, surrounding the solar cell chip array; and
a first optical element array disposed over the carrier wafer to concentrate sunbeams onto the solar cell chip array, wherein the first optical element array is spaced apart from the carrier wafer by the first spacer dam.

2. The solar package structure as claimed in claim 1, wherein the first optical element array comprises a first transparent plate and a first lens array having a plurality of first lenses formed thereon.

3. The solar package structure as claimed in claim 2, wherein each of the first lenses is a biconvex lens having a first convex surface facing a direction of the sunbeams and a second convex surface facing the solar cell chip.

4. The solar package structure as claimed in claim 3, wherein the second convex surface is a wave-shaped surface.

5. The solar package structure as claimed in claim 2, further comprising a plurality of transparent molds disposed directly under the first lens array, respectively encapsulating the solar cell chip array, wherein each of the transparent molds has a convex surface facing the first optical element.

6. The solar package structure as claimed in claim 5, wherein each of the first lenses is a plano-convex lens having a convex surface facing a direction of the sunbeams and a plane surface facing the solar cell chip array.

7. The solar package structure as claimed in claim 2, further comprising a second optical element array comprising a second transparent plate with a second lens array having a plurality of second lenses formed thereon disposed over the first optical element array, wherein the first and second optical element arrays are spaced apart from each other by a second spacer dam.

8. The solar package structure as claimed in claim 7, wherein each of the first lenses is a positive lens having a wave-shaped surface facing a direction of the sunbeams and each of the second lenses is a plano-convex lens having a convex surface facing the direction of the sunbeams.

9. The solar package structure as claimed in claim 8, further comprising a plurality of transparent molds disposed directly under the first and second lens arrays, respectively encapsulating the solar cell chips, wherein each of the transparent molds has a convex surface facing the first optical element.

10. The solar package structure as claimed in claim 1, wherein the solar cell chip array has a plurality of solar cell chips, wherein each of the solar cell chips has a first electrode and a second electrode, and the conductive pattern layer has a plurality isolated conductive patterns electrically connecting to the first and second electrodes, respectively.

11. A method for fabricating a solar package structure, comprising:
providing a carrier wafer;
forming a conductive pattern layer on the carrier wafer;
disposing a solar cell chip array having a plurality of solar cell chips on the conductive pattern layer, wherein each of the solar cell chips electrically connects to the conductive pattern layer;
disposing a first spacer dam on the carrier wafer, surrounding the solar cell chip array; and
disposing a first optical element array over the carrier wafer to concentrate sunbeams onto the solar cell chip array, wherein the first optical element array is spaced apart from the carrier wafer by the first spacer dam.

12. The method for fabricating a solar package structure as claimed in claim 11, wherein the first optical element array comprises a first transparent plate and a first lens array having a plurality of first lenses formed thereon, wherein each of the first lenses is directly over each of the solar cell chips.

13. The method for fabricating a solar package structure as claimed in claim 12, wherein each of the first lenses is a biconvex lens having a first convex surface facing a direction of the sunbeams and a second convex surface facing the solar cell chip.

14. The method for fabricating a solar package structure as claimed in claim 13, wherein the second convex surface is a wave-shaped surface.

15. The method for fabricating a solar package structure as claimed in claim 12, further comprising forming a plurality of transparent molds directly under the first lens array, respectively encapsulating the solar cell chips, wherein each of the transparent molds has a convex surface facing the first optical element.

16. The method for fabricating a solar package structure as claimed in claim 15, wherein each of the first lenses is a plano-convex lens having a convex surface facing a direction of the sunbeams and a plane surface facing the solar cell chips.

17. The method for fabricating a solar package structure as claimed in claim 12, further comprising:
disposing a second spacer dam on the first optical element array; and
disposing a second optical element array with a second lens array formed thereon over the first optical element array, wherein the first and second optical element arrays are spaced apart from each other by the second spacer dam.

18. The method for fabricating a solar package structure as claimed in claim 17, wherein each of the first lenses is a positive lens having a wave-shaped surface facing a direction of the sunbeams and the second lens array has a plurality of second lenses, wherein each of the second lenses is a plano-convex lens having a convex surface facing the direction of the sunbeams.

19. The method for fabricating a solar package structure as claimed in claim 18, further comprising forming a plurality of transparent molds directly under the first and second lens array, respectively encapsulating the solar cell chip, wherein each of the transparent molds has a convex surface facing the first optical element array before disposing the first spacer dam is disposed on the carrier wafer.

20. The method for fabricating a solar package structure as claimed in claim 11, wherein each of the solar cell chips has a first electrode and a second electrode, and the conductive pattern layer has a plurality isolated conductive patterns electrically connecting to the first and second electrodes, respectively.
